(19) United States
(12) Patent Application Publication
(10) Pub. No.: US 2019/0381473 A1
(43) Pub. Date: Dec. 19, 2019

(54) METHOD FOR PRODUCING NUCLEIC ACID ARRAY AND DEVICE FOR PRODUCING NUCLEIC ACID ARRAY

(71) Applicant: Nikon Corporation, Tokyo (JP)

(72) Inventor: Yusuke KAWAKAMI, Yokohama-shi (JP)

(21) Appl. No.: 16/507,753

(22) Filed: Jul. 10, 2019

Related U.S. Application Data
(63) Continuation of application No. PCT/JP2018/000303, filed on Jan. 10, 2018.

(30) Foreign Application Priority Data
Jan. 12, 2017 (JP) 2017-003310

(51) Int. Cl. B01J 19/00

(52) U.S. Cl. CPC B01J 19/0046; B01J 2219/00736; G03F 7/16; B01J 2219/00626; B01J 2219/00596

(57) ABSTRACT

A method for producing a nucleic acid array which includes (a) a step of forming a layer (a PAG layer) made of a resin composition containing a photoacid generator (PAG) for generating an acid as a result of being exposed to light on a solid phase which has a molecule immobilized thereon and having a functional group protected by an acid-decomposable protective group; (b) a step of exposing a desired position of the PAG layer to light; (c) a step of removing the PAG layer which has been exposed to light; and (d) a step of bringing the solid phase from which the PAG layer has been removed into contact with a nucleotide derivative having an acid-decomposable protective group is provided.

### CROSS-REFERENCE TO RELATED APPLICATION

This is a Continuation Application of International Application No. PCT/JP2018/000303 filed on Jan. 10, 2018, which claims priority on Japanese Patent Application No. 2017-003310, filed on Jan. 12, 2017. The contents of the aforementioned applications arc incorporated herein by reference.

### BACKGROUND

### Field of the Invention

The present invention relates to a method for producing a nucleic acid array and a device for producing a nucleic acid array.

### Background

There are two methods for preparing DNA micro-arrays, i.e., an Affymetrix type developed by Affymetrix and a Stanford type developed at Stanford University. The Affymetrix type is a method of synthesizing DNA above a substrate through a photolithographic process using a photosensitive base. On the other hand, the Stanford type is a method of spotting DNA above a substrate through robot printing technology.

According to the Affymetrix type, it is possible to produce a more highly integrated micro-array. However, according to J. Am. Chem. Soc., 1997, 119 (22), 5081 to 5090, a photosensitive base for patterning is special and it cannot be said that the light response associated with a throughput is sufficient in view of mass productivity.

### SUMMARY

An embodiment according to the present invention is a method for producing a nucleic acid array which includes: (a) a step of forming a layer (a PAG layer) made of a resin composition containing a photoacid generator (PAG) for generating an acid as a result of being exposed to light on a solid phase which has a molecule immobilized thereon and having a functional group protected by an acid-decomposable protective group; (b) a step of exposing a desired position of the PAG layer to light; (c) a step of removing the PAG layer which has been exposed to light; and (d) a step of bringing the solid phase from which the PAG layer has been removed into contact with a nucleotide derivative having an acid-decomposable protective group.

Also, an embodiment according to the present invention is a nucleic acid array production device which includes: a PAG layer formation part which is configured to form a layer (a PAG layer) made of a resin composition containing a PAG for generating an acid as a result of being exposed to light above a solid phase which has molecules immobilized therein and having functional groups protected by acid-decomposable protective groups; a light exposure part which is configured to expose a desired position of the PAG layer to light; a PAG layer removal part which is configured to remove the PAG layer which has been exposed to light; and a nucleotide derivative reaction part which is configured to bring the solid phase from which the PAG layer has been removed into contact with a nucleotide derivative having acid-decomposable protective groups.

### BRIEF DESCRIPTION OF THE DRAWINGS

FIG. 1 is a schematic diagram of a method for producing a nucleic acid array according to an embodiment of the present invention.

FIG. 2 is a schematic diagram of a method for producing a nucleic acid array according to an embodiment of the present invention.

FIG. 3 is a schematic diagram of a device for producing a nucleic acid array according to an embodiment of the present invention.

FIG. 4 is a schematic diagram of a device for producing a nucleic acid array according to an embodiment of the present invention.

FIG. 5 shows the results of mass distribution mapping evaluation for an organic chemical structure of a surface of a substrate which has been subjected to patterning using a time-of-flight secondary ion mass spectrometer (ToF-SIMS) and shows an MS spectrum of a deprotected portion using an acid.

FIG. 6 shows the results of mass distribution mapping evaluation for an organic chemical structure of a surface of a substrate which has been subjected to patterning using a ToF-SIMS and shows an MS spectrum of a deprotected portion using an acid.

FIG. 7 shows the results of mapping evaluation with mass derived from a fragment ion m/z 59 and m/z 303 derived from a protective group in a substrate which has been subjected to patterning when a film thickness of a PAG layer is 8 μm.

FIG. 8 is a schematic view for describing hydroxyl group formation in a portion exposed through patterning.

FIG. 9 shows the results of mapping evaluation with mass derived from a fragment ion m/z 59 and m/z 303 derived from a protective group in a substrate which has been subjected to patterning when a film thickness of a PAG layer is 60 nm.

### DESCRIPTION OF EMBODIMENTS

### <<Method for Producing Nucleic Acid Array>>

In an embodiment, the present invention provides a method for producing a nucleic acid array. The method for producing a nucleic acid in the embodiment includes: (a) a step of forming a layer (a PAG layer) made of a resin composition containing a photo acid generator (PAG) for generating an acid as a result of being exposed to light on a solid phase which has molecules immobilized therein and having functional groups protected by acid-decomposable protective groups; (b) a step of exposing a desired position of the PAG layer; (c) a step of removing the PAG layer which has been exposed to light; and (d) a step of bringing the solid phase from which the PAG layer has been removed into contact with a nucleotide derivative having acid-decomposable protective groups.

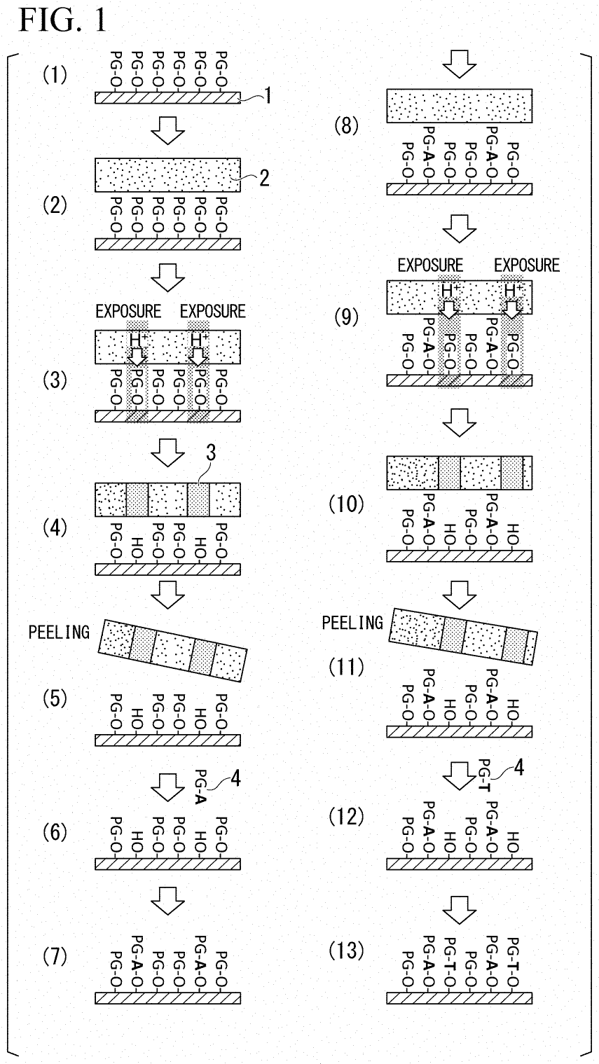

The production method of the embodiment will be described in brief with reference to (1) to (7) of FIG. 1.

First, as shown in (1) of FIG. 1, a solid phase 1 such as a substrate which has molecules immobilized therein and having functional groups protected by acid-decomposable protective groups is prepared. In the example of (1) of FIG. 1, the functional groups protected by the acid-decomposable protective groups are hydroxyl groups (—OH). Furthermore, in the drawing, “PG” is an acid-decomposable protective group. Subsequently, as shown in (2) of FIG. 1, a PAG layer 2 is formed using a resin composition containing a photo acid generator (PAG). After that, as shown in (3) of FIG. 1, the PAG layer 2 is subjected to pattern light exposure. Thus, a PAG in the PAG layer of the light-exposed portion generates an acid, and as shown in (4) of FIG. 1, acid-decomposable protective groups are deprotected from an underlayer of the PAG layer 2 of the light-exposed portion. Subsequently, the PAG layer 2 which has been exposed to light is removed from the solid phase 1. In the example of (5) of FIG. 1, the PAG layer 2 is removed through peeling. After the PAG layer 2 has been removed, as shown in (6) of FIG. 1, a nucleotide derivative 4 having the acid-decomposable protective groups is caused to act. It should be noted that, in the example of (6) of FIG. 1, the nucleotide derivative 4 is an adenine nucleotide derivative. The nucleotide derivative 4 reacts with the deprotected functional groups, and as shown in (7) of FIG. 1, is held on the solid phase 1 via the functional groups.

The steps will be described in detail below.

### [PAG Layer Formation Step]

The step (a) is a step of forming the layer (the PAG layer) made of the resin composition containing the photo acid generator (PAG) for generating the acid as a result of being exposed to light on the solid phase which has the molecules immobilized therein and having the functional groups protected by the acid-decomposable protective groups.

In the step (a), first, as shown in (1) of FIG. 1, the solid phase 1 which has the molecules immobilized therein and having the functional groups protected by the acid-decomposable protective groups (PG) is prepared. As the solid phase 1, for example, a substrate, beads, and the like can be used. When a substrate is used, examples of a material of the substrate include silicon, glass, quartz, soda lime glass, a polyamide resin, a plastic film, and the like, but the present invention is not limited thereto.

Acid-decomposable protective groups are groups that are deprotected due to the action of an acid. In the embodiment, the acid-decomposable protective groups are not particularly limited and can be used with no particular limitation as long as the acid-decomposable protective groups are deprotected due to the action of an acid. Examples of the acid-decomposable protective groups include acetyl groups (Ac); benzoyl groups (Bz); ether-based protective groups such as trityl groups (Tr), monomethoxytrityl groups (MMT), dimethoxytrityl groups (DMT), and trimethoxytrityl groups (TMT); acetal-based protective groups such as β-methoxyethoxymethylether (MEM), methoxy methyl ether groups (MOM), and tetrahydropyranyl groups (THP); silyl ether groups such as t-butyldimethylsilyl groups (TBS), and the like, but the present invention is not limited thereto. These acid-decomposable protective groups are used when the functional groups to be protected are hydroxyl groups. Even when the functional groups to be protected are amino groups or the like, suitable acid-decomposable protective groups can be appropriately selected and used. Examples of the acid-decomposable protective groups include a dimethoxytrityl (DMT) group.

In the embodiment, the functional groups of the molecules immobilized on the solid phase are protected by the acid-decomposable protective groups. The functional groups are not particularly limited as long as the functional groups can bind to the nucleotide derivative which will be described later. Examples of the functional groups include a hydroxyl group.

The method for preparing the solid phase which has the molecules immobilized therein and having the functional groups protected by the acid-decomposable protective groups is not particularly limited. For example, the method can be performed by fixing an organosilane compound molecule to a surface of the solid phase and causing the molecules having the acid-decomposable protective groups to bind to the organosilane compound molecule.

As a method for immobilizing an organosilane compound on a surface of a solid phase, for example, the surface of the solid phase is subjected to plasma treatment using oxygen gas or the like and then is caused to react to the organosilane compound in water or ethanol. Examples of the organosilane compound used in the method include hydroxyalkylsilanes, hydroxyalkyl amidosilanes, hydroxy glycol silane, and the like. For example, N-(3-triethoxysilylpropyl)-4-hydroxybutylamide) and the like can be used.

For example, the solid phase is subjected to the plasma treatment, is then immersed in an organosilane compound solution and heated at about 70 to 120° C. for about 5 to 40 minutes, and then is immersed and cleaned in an organic solvent such as isopropanol. It should be noted that, at the time of cleaning, ultrasonic treatment may be performed. After the cleaning, the solid phase is dried and heated at about 100 to 140° C. for about 1 to 10 minutes and thus the organosilane compound molecule can be fixed to the solid phase.

Subsequently, the molecules having the acid-decomposable protective groups are caused to react to the organosilane compound molecule immobilized in the solid phase. Examples of the molecules having the acid-decomposable protective groups include nucleic acid monomers and the like applicable to a phosphoroamidite method and a phosphate ester method known as nucleic acid artificial synthesis methods such as phosphoroamidite nucleotides having acid-decomposable protective groups and nucleotides whose 5′ or 3′ hydroxyl group is protected with acid-decomposable protective groups. Examples of such molecules include DMT-phosphoroamidite nucleotides. For example, molecules having acid-decomposable protective groups can be immobilized on a surface of a solid phase having an organosilane compound immobilized therein by immersing the solid phase in a phosphoroamidite nucleotide solution having acid-decomposable protective groups and shaking the mixture for about 1 to 15 minutes. This reaction may be performed under water-free conditions. After the reaction, the mixture may be appropriately cleaned with an organic solvent such as acetonitrile.

It should be noted that, although the molecules having the acid-decomposable protective groups are caused to bind to the organosilane compound molecule in the above example, the organosilane compound molecule may be protected directly with acid-decomposable protective groups.

As shown in (2) of FIG. 1, the PAG layer 2 is formed on the solid phase prepared as described above using the resin composition containing the PAG.

The PAG is molecules for generating an acid as a result of being exposed to light. In the production method of the embodiment, the PAG is not particularly limited and can be one generally used for a resist composition and the like. Examples of the PAG include onium salts such as sulfonium salts and iodonium salts, diazomethanes, sulfonic acid esters, and the like. An ionic type such as an onium salt can produce an acid stronger than that of a nonionic type such as a diazomethane or a sulfonic acid ester. For example, the PAG is an onium salt. Examples of onium salts include sulfonium salts such as triphenylsulfonium trifluoromethanesulfonate, iodonium salts such as diphenyliodonium perfluoropropanesulfonate, and the like. Examples of the acid generated from such onium salts include fluoroantimonate (HsbF₆), fluoroalkyl phosphates (FAPs), trifluoromethanesulfonic acid (CF₃SO₃H; TfOH), perfluoropropanesulfonic acid, and the like. The acid generated by the PAG used in the production method of the embodiment has, for example, an acid dissociation constant (pKa) of about −30 to 5. Furthermore, for example, pKa is −25 to 0. In addition, although the PAG having the solubility with respect to a solvent of about 1% by mass or more can be used, a PAG having a higher solubility may be used. As the PAG, for example, a PAG having a solubility of 30% by mass or more, 40% by mass or more, or 50% by mass or more with respect to propylene glycol monomethyl ether acetate (PGMEA) may be used. A PAG that is commercially available for a resist or the like can also be used as the PAG. For example, a PAG of the CPI (registered trademark) series manufactured by San-Apro Ltd. can be used. As the PAG of the CPI (registered trademark) series, CPI-210S is an exemplary example.

The resin composition containing the PAG contains a resin in addition to the PAG. The resin is not particularly limited as long as light of a wavelength at which the PAG contained in the resin composition together with the resin generates an acid is transmitted through the resin. By using the resin through which light is transmitted, when the resin composition is exposed to light, the light of the wavelength reaches the PAG in the resin composition and the PAG generates an acid. The resin through which the light of the wavelength at which the PAG is caused to generate an acid is transmitted (hereinafter referred to as a “light transmitting resin”) may be appropriately selected in accordance with a type of the PAG. If the resin is a transparent resin having a high light transmitting property, light of a wavelength at which a general PAG is caused to generate an acid is transmitted through the resin. Thus, this transparent resin can be used as the light transmitting resin. Examples of such resins include polyurethane resins; acrylate resins such as poly(methyl methacrylate) resins; imide resins; amide resins; sulfone resins; vinyl resins; silicone resins; polyolefin resins such as polyethylene and polypropylene; polystyrenes; polycarbonates; polyesters such as polyester terephthalate; epoxy resins; hydrophilic resins such as polysaccharides and polyols; water repellent resins such as perfluoroether, and the like, but the present invention is not limited thereto. The PAG and the light transmitting resin may be combined in a manner in which they are dissolved or dispersed in each other as long as the PAG in the resin composition after film formation generates an acid.

It should be noted that, if a resin with high peelability is used as the light transmitting resin, it is possible to remove the PAG layer through peeling in the subsequent step (c). Polyurethane resins, silicone resins, acrylate resins, and the like are exemplary examples of resins with high peelability, but the present invention is not limited to these.

Commercially available resins may be used as the light transmitting resin. For example, as commercially available items of polyurethane resins, RusPack (Audec Corporation) and the like are exemplary examples.

A type of light transmitting resin may be used independently and two or more types of light transmitting resins may be used together.

The resin composition may contain other components in addition to the PAG and the light transmitting resin. As the other components, for example, solvents, additives and the like generally used for preparation of resin products, and the like are exemplary examples. It is also possible to add a basic substance, a surfactant, and the like for the purpose of keeping the inside of the resin basic to neutral. It is also possible to add a basic substance for the purpose of minimizing thermal diffusion of an acid generated from a PAG. As the basic substance, for example, an alkylamine and the like may be added. Furthermore, additives for enhancing the releasability of the resin composition may be added as long as the additives do not minimize an interfacial deprotection reaction of an acid generated from the PAG. For example, a silicone based release agent may be added.

The resin composition can be prepared, for example, by dissolving a PAG and a light transmitting resin in a solvent, appropriately adding other components, and stirring the mixture. The solvent may be appropriately selected in accordance with types of the PAG and the light transmitting resin. Generally used organic solvents and the like can be used as the solvent. Examples of the solvent include alcohol-based solvents such as ethanol, butanol, isopropyl alcohol, isobutyl alcohol, and benzyl alcohol; ether-based solvents such as propylene glycol monoethyl ether (PGME) and PGMEA; ketone-based solvents such as acetone and cyclohexane; ester-based solvents such as ethyl acetate, butyl acetate, and isopropyl acetate; and hydrocarbon-based solvents such as toluene, xylene, and cyclohexane, but the present invention is not limited. It should be noted that one type of solvent may be used independently or two or more mixed solvents may be used.

Although the amount of the PAG is not particularly limited in the resin composition, for example, it is possible to set the amount of the PAG to 0.005 to 20 parts by mass, 0.5 to 15 parts by mass, 1 to 10 parts by mass, and the like with respect to 100 parts by mass of the light transmitting resin.

Also, although the amount of the light transmitting resin in the resin composition is not particularly limited, for example, it is possible to set the amount of the light transmitting resin to 0.1 to 70% by mass, 0.5 to 60% by mass, 1 to 50% by mass, and the like with respect to 100% by mass of the resin composition. When the amount of the light transmitting resin in the resin composition is reduced, a PAG layer having a thin film thickness can be formed.

The PAG layer using the resin composition may be formed through a method generally used for the formation of a resist film and the like. For example, a spin coat method, a dip coat method, a slit die coat method, a spray coat method, or the like can be used to form the PAG layer. After a film is formed through the above-described method, the film may be dried through heating or the like.

The film thickness of the PAG layer is not particularly limited, but can be, for example, about 10 to 20000 nm and about 30 to 10000 nm. When the film thickness is thinner, a finer array can be produced. On the other hand, if the film thickness is increased, it is possible to remove the PAG layer through peeling. Although the peelable film thickness varies depending on a type of the light transmitting resin, for example, a peelable film thickness of 1000 nm or more is an exemplary example. Therefore, the film thickness may be appropriately selected in accordance with the degree of refinement of the array. For example, when the PAG layer is removed through peeling, the film thickness can be about 1000 to 20000 nm or about 1000 to 10000 nm.

### [Light Exposure Step]

The step (b) is a step of exposing a desired position of the PAG layer formed in the above step (a) to light.

As shown in (3) of FIG. 1, when the PAG layer 2 is subjected to pattern light exposure, an acid (H⁺) is generated from the PAG contained in the PAG layer 2 in the light-exposed portion. The acid-decomposable protective groups (PG) present in the underlayer of the PAG layer 2 are deprotected by this acid and the functional groups protected by the acid-decomposable protective groups are exposed. It should be noted that (4) of FIG. 1 shows the PAG layer which has been exposed to light. In (4) of FIG. 1, an acid is generated in an light-exposed portion 3 of the PAG layer 2, the acid-decomposable protective groups in the underlayer thereof are deprotected, and the functional groups (—OH) are exposed.

Light exposure in the step (b) can be performed using an appropriate light source configured to radiate g rays, h rays, i rays, an ArF excimer laser, a KrF excimer laser, an EUV, a VUV, an EB, X rays, or the like in accordance with a type of PAG. For example, when a PAG for ArF is used, it is possible to perform light exposure using an ArF excimer laser. Furthermore, when a PAG for i rays is used, it is possible to perform light exposure using i rays.

In the light exposure in the step (b), an amount of light exposure is not particularly limited, but can be, for example, 10 to 600 mJ/cm² or 50 to 200 mJ/cm². In a method for producing an Affymetrix type DNA micro-array, several J or more are necessary for deprotection of photosensitive bases, and in the production method of the embodiment, a nucleic acid array can be produced with a smaller amount of light exposure as compared to the Affymetrix type method.

The light exposure is performed only on the PAG layer at a position at which the nucleotide derivative is caused to bind in a step of bringing the PAG layer into contact with the nucleotide derivative having the acid-decomposable protective groups which will be described later. By performing such pattern light exposure, only the acid-decomposable protective groups present on the underlayer of a portion which has been exposed to light of the PAG layer are deprotected and acid-decomposable protective groups of a non-light-exposed portion remain without being deprotected. In the case of such pattern light exposure, for example, a method for performing pattern light exposure using a photomask or the like, a means for projection light exposure using an optical system such as a lens and a mirror, and maskless light exposure using a spatial light modulation element, a laser beam, and the like can be used.

### [PAG Layer Removal Step]

The step (c) is a step of removing the PAG layer which has been exposed to light in the step (b).

In the example shown in (5) of FIG. 1, the removal of the PAG layer 2 is performed by peeling the PAG 2 from the solid phase 1.

Although the method for removing the PAG layer is not particularly limited, a method for peeling the PAG layer from the solid phase, a method for dissolving the PAG layer using a solvent, and the like is an exemplary example.

When the PAG layer is peeled from the solid phase, the method for performing peeling is not particularly limited. For example, the method for holding one end of the PAG layer and performing peeling, a method for bringing an adhesive base material into contact with the PAG layer and performing peeling, and the like is an exemplary example. As an example of the peeling method, a method using roll to roll technology and the like is an exemplary example.

After the peeling of the PAG layer, the solid phase may be cleaned to remove the residue of the PAG layer remaining on the solid phase. The cleaning may be performed using an organic solvent or the like and examples of such a solvent include acetone, isopropyl alcohol, and the like. Furthermore, in order to enhance the cleaning effect, vapor cleaning using solvent steam may be performed. In addition, in order to enhance the cleaning effect, the solid phase may be irradiated with ultrasonic waves during the cleaning operation.

When the PAG layer is dissolved using a solvent, a solvent capable of dissolving the light transmitting resin may be appropriately selected in accordance with a type of light transmitting resin contained in the resin composition and the PAG layer may be dissolved. As the solvent, acetone, isopropyl alcohol, and the like are exemplary examples, but the present invention is not limited thereto. Furthermore, in order to enhance the dissolution effect, a substrate may be irradiated with ultrasonic waves during the dissolution operation.

After the dissolving of the PAG layer, the solid phase may be cleaned to remove the residue of the PAG layer remaining on the solid phase. The cleaning may be performed using an appropriate organic solvent or the like, and as such a solvent, acetone, isopropyl alcohol, and the like are exemplary examples. Furthermore, in order to enhance the cleaning effect, vapor cleaning using solvent steam may be performed. In addition, in order to enhance the cleaning effect, a substrate may be irradiated with ultrasonic waves during the cleaning operation.

### [Nucleotide Derivative Reaction Step]

The step (d) is a step of bringing the solid phase from which the PAG layer has been removed in the above step (c) into contact with the nucleotide derivative having the acid-decomposable protective groups.

As shown in (6) and (7) of FIG. 1, when the nucleotide derivative 4 having the acid-decomposable protective groups (PG) is brought into contact with the solid phase 1 from which the PAG layer 2 has been removed, the nucleotide derivative 4 is coupled with and binds to the functional groups (—OH) which has been exposed through the deprotection. Thus, nucleic acid synthesis with a desired sequence can be performed at a desired position on the solid phase 1.

In the case of the nucleotide derivative having the acid-decomposable protective groups, a nucleotide derivative used for a general nucleic acid synthesis method can be used. As the nucleic acid synthesis method, for example, a phosphoroamidite method is an exemplary example, and as the nucleotide derivative, phosphoroamidated nucleotide derivatives can be used. Furthermore, the acid-decomposable protective groups can be used without particularly limitation as long as the acid-decomposable protective groups are deprotected due to the action of an acid. As the acid-decomposable protective groups, for example, acid-decomposable protective groups described in the above-described “[PAG layer formation step]” and the like are exemplary examples. For example, DMT can be used as one of the acid-decomposable protective groups. Furthermore, as the functional groups protected by the acid-decomposable protective groups, a hydroxyl group binding to a carbon atom at the 5-position of ribose or deoxyribose is an exemplary example, but the present invention is not limited. Examples of the nucleotide derivative which can be used in this step include DMT-dA phosphoroamidite, DMT-dT phosphoroamidite, DMT-dG phosphoroamidite, DMT-dC phosphoroamidite, and the like, but the present invention is not limited thereto. Nucleotide derivatives commercially available for nucleic acid synthesis may be used as the nucleotide derivative. Furthermore, a nucleotide from which the nucleotide derivative is derived may be RNA and artificial nucleic acids such as bridged nucleic acids (BNA) and peptide nucleic acids (PNA).

When the phosphoroamidated nucleotide derivative is used as the nucleotide derivative, the reaction of the nucleotide derivative with the functional groups on the solid phase can be performed under the conditions used in a general phosphoroamidite method. For example, nucleic acid synthesis using the phosphoroamidite method can be performed in accordance with the following procedure.

First, the phosphoroamidated nucleotide derivative is activated with tetrazole or the like and the nucleotide derivative is coupled with the functional groups on the solid phase. Subsequently, the unreacted functional groups are capped through acetylation or the like not to participate in the subsequent cycles. After that, the binding of the functional groups on the solid phase to the nucleotide derivative is oxidized using iodine so that trivalent phosphorus is converted to pentavalent phosphate ester.

These reactions are known and can be performed under known conditions. Furthermore, commercially available reagents can be used as a reagent used for these reactions. It should be noted that the above-described method is an example of a method for binding the functional groups on the solid phase to the nucleotide derivative and the binding reaction may be performed using other methods.

Before the reaction with the nucleotide derivative is performed, the solid phase may be dried. In the case of the drying, for example, dried acetonitrile, nitrogen flow, and the like can be used. Furthermore, the binding reaction of the functional groups on the solid phase to the nucleotide derivative may be performed under water-free conditions.

### [Nucleic Acid Extension]

The production method in the embodiment can perform nucleic acid extension on the solid phase and produce a nucleic acid array having a desired sequence and base length by repeatedly performing the steps (a) to the step (d) any number of times. For example, when a DNA array is produced, the DNA array can be produced by synthesizing DNA having an arbitrary sequence and a base length on the solid phase 1 by repeatedly performing the steps (a) to the step (d) using four types of nucleotide derivatives having adenine, thymine, cytosine, and guanine as a basic group.

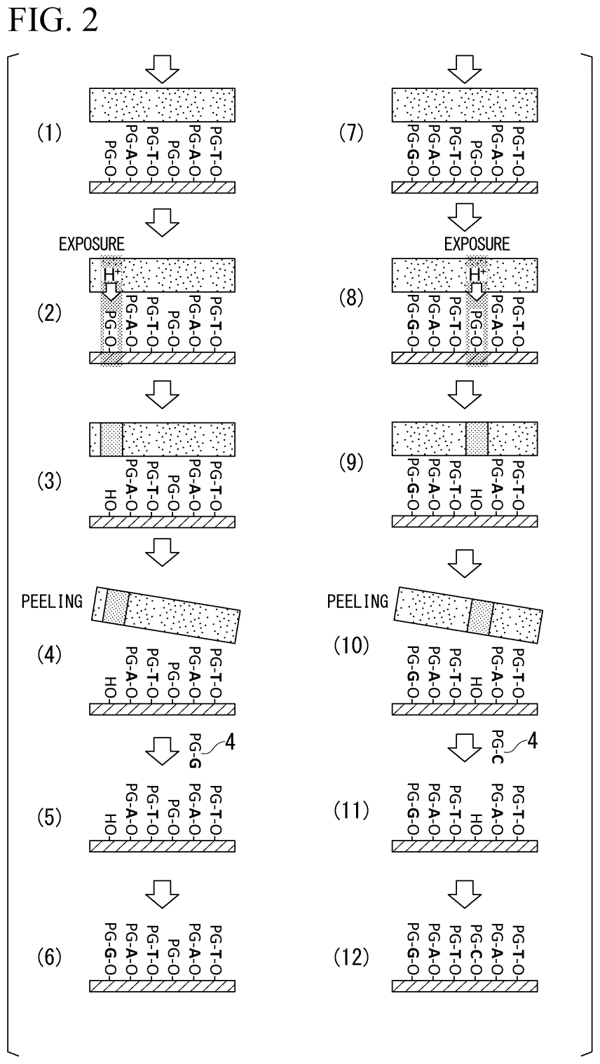

An example of DNA synthesis on the solid phase will be described below with reference to (1) to (13) of FIG. 1 and (1) to (12) of FIG. 2.

(1) to (7) of FIG. 1 show steps (a) to (d) in a first round. Details are as described above. In (1) to (7) of FIG. 1, as the nucleotide derivative 4, the adenine nucleotide derivative binds to the functional groups (—OH) on the solid phase 1.

(8) to (13) of FIG. 1 show steps (a) to (d) in a second round. In (8) of FIG. 1, a PAG layer 2 is formed again on the solid phase 1 binding to the adenine nucleotide derivative in the steps (a) to (d) in the first round (step (a)). In (9) of FIG. 1, a position of the PAG layer 2 different from that in the first round is subjected to light exposure, and thus a PAG in the PAG layer 2 in the portion which has been exposed to light generates an acid, and as shown in (10) of FIG. 1, the acid-decomposable protective groups (PG) on the underlayer of a portion 3 which has been exposed to light in the PAG layer 2 is deprotected (step (b)). Subsequently, as shown in (11) of FIG. 1, the PAG layer 2 which has been exposed to light is removed (step (c)). In the example of (11) of FIG. 1, the PAG layer 2 which has been exposed to light is removed through peeling. Furthermore, as shown in (12) of FIG. 1, the solid phase 1 from which the PAG layer 2 has been removed is brought into contact with the nucleotide derivative 4 having the acid-decomposable protective groups (PG) (step (d)). In the example of (12) of FIG. 1, as the nucleotide derivative 4, a thymidine nucleotide derivative is caused to act on the functional groups (—OH) on the solid phase 1. As a result, as shown in (13) of FIG. 1, the thymidine nucleotide derivative binds to the functional groups (—OH) on the solid phase 1.

(1) to (6) of FIG. 2 show steps (a) to (d) in a third round. In (1) of FIG. 2, a PAG layer 2 is formed again on the solid phase 1 binding to the adenine nucleotide derivative in the first round and the thymidine nucleotide in the second round (step (a)). In (1) of FIG. 2, a position of the PAG layer 2 different from those in the first round and in the second round is subjected to light exposure, and thus a PAG in the PAG layer 2 in the portion which has been exposed to light generates an acid, and as shown in (3) of FIG. 2, the acid-decomposable protective groups (PG) on the underlayer of a portion 3 which has been exposed to light in the PAG layer 2 is deprotected (step (b)). Subsequently, as shown in (4) of FIG. 2, the PAG layer 2 which has been exposed to light is removed (step (c)). In the example of (4) of FIG. 2, the PAG layer 2 which has been exposed to light is removed through peeling. Furthermore, as shown in (5) of FIG. 2, the solid phase 1 from which the PAG layer 2 has been removed is brought into contact with the nucleotide derivative 4 having the acid-decomposable protective groups (PG) (step (d)). In the example of (5) of FIG. 2, as the nucleotide derivative 4, a guanine nucleotide derivative is caused to act on the functional groups (—OH) on the solid phase 1. As a result, as shown in (6) of FIG. 2, the guanine nucleotide derivative binds to the functional groups (—OH) on the solid phase 1.

(7) to (12) of FIG. 2 shows steps (a) to (d) in a fourth round. In (7) of FIG. 2, the PAG layer 2 is formed again on the solid phase 1 binding to the adenine nucleotide derivative in the first round, the thymidine nucleotide in the second round, and the guanine nucleotide in the third round (step (a)). In (8) of FIG. 2, a position of the PAG layer 2 different those in the first round to the third round is subjected to light exposure, and thus a PAG in the PAG layer 2 in a portion which has been exposed to light generates an acid, and as shown in (9) of FIG. 2, the acid-decomposable protective groups (PG) on the underlayer of a portion 3 which has been exposed to light in the PAG layer 2 is deprotected (step (b)). Subsequently, as shown in (10) of FIG. 2, the PAG layer 2 which has been exposed to light is removed (step (c)). In the example of (10) of FIG. 2, the PAG layer 2 which has been exposed to light is removed through peeling. Furthermore, as shown in (11) of FIG. 2, the solid phase 1 from which the PAG layer 2 has been removed is brought into contact with the nucleotide derivative 4 having the acid-decomposable protective groups (PG) (step (d)). In the example of (11) of FIG. 2, as the nucleotide derivative 4, the cytosine nucleotide derivative is caused to act on the functional groups (—OH) on the solid phase 1. As a result, as shown in (12) of FIG. 2, the cytosine nucleotide derivative binds to the functional groups (—OH) on the solid phase 1.

As described above, in the example of FIGS. 1 and 2, a nucleotide at a first stage is caused to bind to the solid phase 1 by repeatedly performing the steps (a) to (d) four times. Similarly, by repeatedly further performing the steps (a) to (d) four times, a nucleotide at a second stage can be caused to bind to the nucleotide at the first stage. Similarly, by repeatedly further performing the steps (a) to (d) four times, a nucleotide at a third stage can be caused to bind to the nucleotide at the second stage. In this way, a desired sequence of the base length can be synthesized on the solid phase 1 by using the steps (a) to (d) four times in which each nucleotide derivative of adenine, thymine, guanine, and cytosine is used each time as one set and performing the set a desired number of times. For example, by performing the set ten times, DNA with ten basic groups can be synthesized on the solid phase 1.

In this way, by repeatedly performing the steps (a) to (d) an arbitrary number of times, a nucleic acid having a desired sequence can be synthesized at a desired position on the solid phase 1. In this way, a nucleic acid array can be produced, for example, by synthesizing a nucleic acid with 10 to 100 basic groups having an arbitrary sequence on the solid phase 1.

It should be noted that, although the nucleotide derivative is caused to react with adenine, thymine, guanine, and cytosine in this order in the example of FIGS. 1 and 2, the sequence of reacting the nucleotide derivative is not limited to this and these nucleotide derivatives can be caused to react in an arbitrary sequence. Furthermore, the sequence in which the nucleotide derivative is caused to react does not have to be the same in each set and the nucleotide derivative may be caused to react in a different sequence for each set.

Also, although the nucleotide extends on the solid phase one step at a time in the above-described example, it is not necessary to extend the nucleotide one step at a time. For example, when a adenine nucleotide derivative is used in the first round and a thiamine nucleotide derivative is used in the second round, a position at which the adenine nucleotide derivative and the thiamine nucleotide derivative partially overlap may be subjected to light exposure in the first round and the second round and an array of “A-T” may be formed at a position at which the light exposures in the first round and the second round overlap.

According to the production method in the embodiment, a nucleic acid array can be produced using a smaller amount of light exposure than that of a conventional method. Furthermore, since a light transmitting resin which is easily obtained and inexpensive can be used as the light transmitting resin, the cost of nucleic acid synthesis can be reduced. In addition, the fining of an array is also possible by controlling the film thickness and pattern light exposure of the light transmitting resin.

For this reason, according to the production method in the embodiment, it is possible to provide a method for producing a nucleic acid array which enables the fining of an array and has a high throughput.

### <<Device for Producing Nucleic Acid Array>>

In an embodiment, the present invention provides a device for producing a nucleic acid array for realizing the method for producing a nucleic acid array in the embodiment. The device for producing a nucleic acid array in the embodiment includes: a PAG layer formation part which is configured to form a layer (a PAG layer) made of a resin composition containing a PAG for generating an acid as a result of being exposed to light on a solid phase which has molecules immobilized therein and having functional groups protected by acid-decomposable protective groups; a light exposure part which is configured to expose a desired position of the PAG layer to light; a PAG layer removal part which is configured to remove the PAG layer which has been exposed to light; and a nucleotide derivative reaction part which is configured to bring the solid phase from which the PAG layer has been removed into contact with a nucleotide derivative having acid-decomposable protective groups.

An example of a constitution of the device for producing a nucleic acid array in the embodiment will be described below.

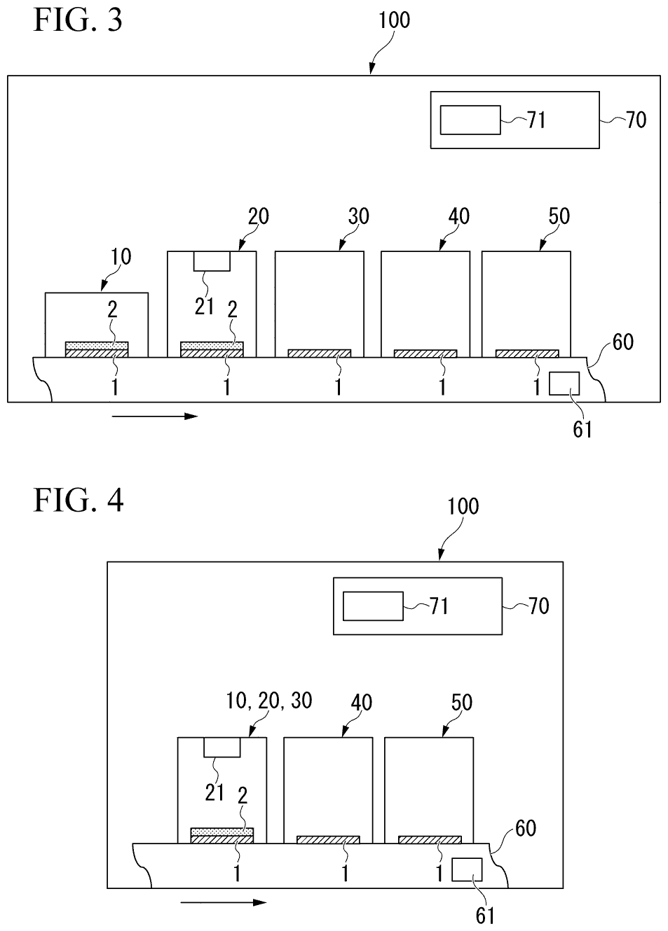

FIG. 3 shows an example of a constitution of the device for producing a nucleic acid array in the embodiment. In the example of the device shown in FIG. 3, a nucleic acid array production device 100 includes a PAG layer formation part 10, a light exposure part 20, a PAG layer removal part 30, and a nucleotide derivative reaction part 40.

The PAG layer formation part 10 has a mechanism for forming a PAG layer 2 on a solid phase 1 which has molecules immobilized therein and having functional groups protected by acid-decomposable protective groups. The PAG layer formation part 10 can include, for example, a solid phase holding part which holds the solid phase 1, a resin composition application part which applies a resin composition on the solid phase 1, a spin coat part which spin-coats a resin composition on the solid phase 1, a drying part which dries the PAG layer which has been formed through spin coating or the like, and the like. A film made of the resin composition may be formed on the solid phase through a dip coater, a slit die coater, a spray coater, or the like as well as a spin coater. In this case, the PAG layer formation part includes a dip coating part, a slit die coating part, or a spray coating part instead of the spin coat part. Furthermore, the PAG layer formation part 10 may optionally include a plasma treatment part which performs plasma treatment on the solid phase, a silanization part which causes an organosilane compound to bind to (perform silanization on) a surface of the solid phase, and the like.

The light exposure part 20 includes a mechanism for exposing a desired position of the PAG layer 2 to light. The light exposure part 20 can include a light source 21 for light exposure. Furthermore, a photomask through which a desired position of the PAG layer is exposed to light, a light exposure pattern storage part for storing a light exposure pattern, and the like may be provided. In addition, means for projection light exposure using an optical system such as a lens and a mirror, maskless light exposure using a spatial light modulation element and a laser beam, and the like may be provided instead of the photomask.

The PAG layer removal part 30 has a mechanism for removing the PAG layer 2 which has been exposed to light. When the PAG layer 2 is removed through peeling, the PAG layer removal part 30 can include a PAG layer gripping and peeling part which holds and peels off one end of the PAG layer, a solid phase holding part which holds the solid phase 1, and the like. Furthermore, a PAG layer adhering and peeling part including a base having an adhesive surface may be provided instead of the PAG layer gripping and peeling part. The PAG layer adhering and peeling part adheres the PAG layer 2 by bringing the base having the adhesive surface into contact with a surface of the PAG layer 2 and peels the PAG layer 2 from the solid phase 1. A constitution in which the base having the adhesive surface is formed to have a cylindrical shape and the PAG layer 2 is peeled off by rolling the cylindrical adhesive surface on the surface of the PAG layer 2 may be provided.

Also, when the PAG layer 2 is removed through dissolution using a solvent, the PAG layer removal part 30 can include an immersion tank in which the solid phase 1 is immersed in the solvent, a solvent addition/discharge part using which the solvent in the immersion tank is exchanged, and the like. It should be noted that, since the PAG layer is dissolved at a solid/liquid interface, any dissolution method may be adopted as long as a necessary amount of solvent is in contact with the solid phase 1 and it is not necessary that the dissolution method does not necessarily include immersion. For this reason, a constitution in which a necessary amount of solvent may be applied to the PAG layer using, for example, a slit die coater, a spray coater, or the like instead of the immersion tank may be provided and a constitution in which a minute amount of solvent is applied to the entire PAG layer in a spread manner using a spin coater and then is held for a predetermined time may be provided. With such a constitution, the cost of the solvent can be significantly reduced as compared to the case of performing the immersion method.

Also, the PAG layer removal part 30 may optionally include a cleaning part which cleans the solid phase 1 from which the PAG layer has been removed. When the PAG layer 2 is removed through dissolution using a solvent, the immersion tank configured to dissolve the PAG layer can be also used as a cleaning tank configured to perform cleaning. A steam cleaning tank may be provided as the cleaning tank. Liquid cleaning in the immersion tank or steam cleaning in the steam cleaning tank may be performed independently and cleaning using the steam cleaning tank may be performed after cleaning in the immersion tank.

The nucleotide derivative reaction part 40 has a mechanism for bringing the solid phase from which the PAG layer has been removed into contact with a nucleotide derivative having acid-decomposable protective groups. The nucleotide derivative reaction part 40 can include a reaction tank configured to react a nucleotide derivative, a nucleotide derivative addition part configured to add the nucleotide derivative to the reaction tank, and the like. Furthermore, the nucleotide derivative reaction part 40 may include an atmosphere controller which controls an atmosphere such as a dry atmosphere and an inert atmosphere. After the nucleotide derivative is introduced into the solid phase 1, a reaction tank in which an oxidation reaction/capping reaction performed using a general artificial nucleic acid synthesis method is possible, a chemical solution addition part, a chemical solution addition part configured to add a chemical solution necessary for these reactions, and the like can also be provided. Furthermore, when nucleic acid synthesis is performed using the phosphoroamidite method, an operation part configured to perform various operations of the phosphoroamidite method and the like may be provided.

The nucleic acid array production device 100 optionally includes a cleaning part 50 configured to clean the solid phase 1 into which the nucleotide derivative has been introduced. When the cleaning is performed through dissolution using a solvent, an immersion cleaning tank in which nucleotide introduction reagents and reagents used in an oxidation reaction/capping reaction are removed can also be provided. A steam cleaning tank may be provided as a cleaning layer. A constitution in which liquid cleaning in the immersion tank or steam cleaning in the steam cleaning tank is performed independently and a constitution in which cleaning using the steam cleaning tank is performed after cleaning in the immersion tank may be provided.

When the PAG layer removal part 30 has the cleaning part which cleans the solid phase 1 from which the PAG layer has been removed, all or a part of the cleaning part may also be used as the cleaning part 50.

Also, the nucleic acid array production device 100 may include a solid phase moving part 60 which moves the solid phase 1 to the PAG layer formation part 10, the light exposure part 20, or the PAG layer removal part 30 and a solid phase moving controller 61 which controls the movement of the solid phase moving part 60. Thus, it is possible to efficiently produce a nucleic acid array by automatically moving the solid phase 1 to the PAG layer formation part 10, the light exposure part 20, or the PAG layer removal part 30. The solid phase moving part 60 may also be configured to move the solid phase 1 to the nucleotide derivative reaction part 40 (for example, FIG. 3). After the completion of the reaction in the nucleotide derivative reaction part 40, the solid phase 1 may be configured to return to the PAG layer formation part 10. It should be noted that, although the solid phase moving part 60 has a belt-like constitution in which the parts are connected in the example of FIG. 3, the constitution of the solid phase moving part 60 is not limited, and for example, the solid phase 1 may be configured to move by an arm or the like.

Furthermore, in the nucleic acid array production device 100, the light source 21 of the light exposure part 20 may be disposed above the PAG layer formation part 10 (for example, FIG. 4). For example, when a PAG layer is formed using spin coating, a light source of a light exposure part may be disposed directly above a rotation table of a spin coater. With such a constitution, it is possible to continuously perform the PAG layer formation step and the light exposure step without moving the solid phase 1. In this case, all or a part of the PAG layer formation part 10 is configured to be used as the light exposure part 20 as well.

In addition, in the nucleic acid array production device 100, all or a part of the PAG layer formation part 10 may also be used as the PAG layer removal part 30 (for example, FIG. 4). For example, the PAG layer gripping and peeling part and the PAG layer adhering and peeling part can be provided in the PAG layer formation part 10 and the PAG layer 2 which has been exposed to light can be removed. Furthermore, when the removal of the PAG layer is performed through the dissolution using a solvent, as described above, it is not necessary to necessarily immerse the solid phase in the solvent and it is also possible to perform the removal by applying a small amount of solvent. For this reason, for example, a spin coater, a slit die coater, a spray coater, or the like disposed in the PAG layer formation part 10 may be used for applying a solvent to the PAG layer. With such a constitution, the PAG layer formation step, the light exposure step, and The PAG layer removal step can be continuously performed without moving the solid phase.

The nucleic acid array production device 100 can include a controller 70 which controls an operation of each of the above-mentioned parts, an array arrangement storage part 71 which stores the sequence of each probe in a nucleic acid array, and the like as arbitrary constituent elements in addition to the above-mentioned parts.

An example of an operation of the nucleic acid array production device 100 including the above-described constituent elements will be described.

First, in the PAG layer formation part 10, the PAG layer 2 is formed on the solid phase 1. Furthermore, if necessary, before formation of the PAG layer 2, the solid phase is subjected to plasma treatment and silanization using the plasma treatment part and the silanization part. For example, after silanization, a solid phase has molecules immobilized therein and having functional groups protected by acid-decomposable protective groups is prepared using a method for causing molecules having acid-decomposable protective groups to bind to an organosilane compound on the solid phase. A resin composition is applied on this solid phase using the resin composition application part, a film is formed using the spin coat part or the like, the film is dried using the drying part, and the PAG layer 2 is formed. After the PAG layer 2 is formed in the PAG layer formation part 10, the solid phase 1 is transported to the light exposure part 20 using the solid phase moving part 60.

In the light exposure part 20, pattern light exposure is performed on the PAG layer 2 formed on the solid phase 1. Light exposure is performed by radiating light from the light source 21. In addition, for example, a predetermined position of the PAG layer 2 is exposed to light using a photomask or the like. An amount of light exposure at the light exposure part 20 is controlled to be, for example, 10 to 600 mJ/cm². At the light-exposed position of the PAG layer 2, the PAG generates an acid and the acid-decomposable protective groups located at the underlayer of the light-exposed portion in the PAG layer 2 are deprotected.

After the PAG layer 2 is exposed in the light exposure part 20, the solid phase 1 is transported to the PAG layer removal part 30 using the solid phase moving part 60.

In the PAG layer removal part 30, the PAG layer 2 which has been exposed to light is removed from the solid phase 1. When the PAG layer 2 is removed through peeling, for example, the solid phase 1 is fixed using the solid phase holding part and the peeling is performed while one end of the PAG layer 2 is held using the PAG layer gripping and peeling part. Alternatively, the solid phase 1 is fixed using the solid phase holding part and the PAG layer 2 adheres and peels off using the PAG layer adhering and peeling part.

Also, when the PAG layer 2 is removed through the dissolution using a solvent, for example, the solid phase 1 is immersed in the solvent in an immersion part and the PAG layer 2 is dissolved.

The solid phase 1 from which the PAG layer 2 has been removed is optionally subjected to cleaning using the cleaning part.

After the PAG layer 2 is removed in the PAG layer removal part 30, the solid phase 1 is transported to the nucleotide derivative reaction part 40 using the solid phase moving part 60.

In the nucleotide derivative reaction part 40, the solid phase 1 from which the PAG layer 2 has been removed is brought into contact with a nucleotide derivative having acid-decomposable protective groups. Thus, the nucleotide derivative binds to the functional groups on the solid phase 1. In the nucleotide derivative reaction part 40, for example, the solid phase 1 is brought into contact with the nucleotide derivative in the reaction tank and is subjected to various operations of the phosphoroamidite method.

After the nucleotide derivative binds in the nucleotide derivative reaction part 40, the solid phase 1 is transported to the PAG layer formation part 10 again and is repeatedly subjected to the above-described steps an arbitrary number of times. In this way, it is possible to produce a nucleic acid array having a desired sequence by repeatedly performing the PAG layer formation, the light exposure, the PAG layer removal, and the nucleotide derivative reaction an arbitrary number of times.

It should be noted that, although the solid phase 1 is transported to each of the parts using the solid phase moving part 60 in the above-mentioned example, for example, the solid phase 1 may be held in one place, each of the parts of the nucleic acid array production device 100 may be moved to the fixed position of the solid phase 1 to be subjected to each of the steps.

Although the embodiment of the present invention has been described in detail below with reference to the drawings, the specific constitution thereof is not limited to this embodiment and includes any design and the like without departing the gist of the present invention.

### EXAMPLES

Although the present invention will be described below by way of examples, the present invention is not limited to the following examples.

### Example 1

### [Formation of Linker Layer on Substrate and Introduction of Acid-Decomposable Protective Group]

150 mg of a silane coupling agent (N-(3-triethoxysilylpropyl)-4-hydroxybutylamide manufactured by GELEST, INC.) was weighed in a beaker and 150 mL of ion exchange water heated to 90° C. was added into the beaker. After performing stirring at 90° C. or 5 minutes, 1.5 mL of acetic acid was added and the mixture was additionally heated and stirred for 30 minutes to form a silane solution.

Subsequently, a 3-inch silicon wafer with a 150 nm thermal oxide film serving as a substrate was treated and activated at 400 W×3 times using an atmospheric pressure oxygen plasma device (YAP510: manufactured by Yamato Scientific Co., Ltd.) and then was put into a reaction container and was heated with the silane solution at a set temperature of 90° C. for 20 minutes.

After the heating, the substrate was taken outside of the container, was immersed in isopropanol (IPA), and was subjected to 28 kHz ultrasonic cleaning for 5 minutes, and then was dried using a nitrogen flow. After that, the silane was fixed to the substrate by performing heating at 120° C. for 3 minutes to form a linker layer.

It should be noted that, if necessary, the linker layer was formed only on one side of the substrate by attaching a masking tape (N380 manufactured by Nitto Denko Corporation) to the one side thereof before the plasma treatment and peeling the masking tape before the IPA cleaning.

Subsequently, the following work was performed in a glove box controlled to a nitrogen atmosphere of an oxygen concentration of 0.0% and a humidity of 3.3% or less.

20 mL of an acetonitrile solution of tetrazole (450 mM manufactured by Sigma-Aldrich) and 10 mL of dried acetonitrile (manufactured by Sigma-Aldrich) were added to 1 g of dimethoxytrityl (DMT)-dT phosphoroamidite (manufactured by Sigma-Aldrich). In this way, 30 mL of a 45 mM solution of DMT-dT phosphoroamidite was prepared.

As described above, the substrate having the linker layer formed thereon was immersed in the dried acetonitrile and was dried using a nitrogen flow. After the drying, the substrate was put into a reaction container and shaken with the DMT-dT phosphoroamidite solution for 2 minutes. The substrate was taken outside of the container and the dried acetonitrile was put into another container for transportation with the substrate and taken outside of the glove box.

The substrate was immersed in a container for cleaning containing 100 mL of acetonitrile and subjected to 28 kHz ultrasonic cleaning for 5 minutes. 100 mL of acetonitrile was prepared in another container and the same cleaning was performed twice or more, i.e., a total of 3 times. After the drying using a nitrogen flow, the substrate was stored in a glove box.

### [Preparation of Resin Composition]

PAG (CPI-210S manufactured by San-Apro Ltd.) was added to an alcohol solution (RusPack manufactured by Audeck Co., Ltd.) with a polyurethane concentration of 20% by mass to be 1% by mass (5% by mass with respect to polyurethane). The mixture was stirred using a rotary kneader and further irradiated with 28 kH ultrasonic waves for 5 minutes to completely dissolve the PAG.

### [Formation of PAG Layer]

A layer of the above-mentioned resin composition was spin-formed (1000 rpm and 30 seconds) on the substrate prepared as described above and the above-mentioned resin composition was heated and dried at 90° C. for 1 minute using a hot plate. The film thickness of the PAG layer was 8 μm.

### [Removal of Patterning and PAG Layer]

Pattern light exposure was performed using UV light of 365 nm. The pattern light exposure was performed at intervals of 100 μm so that an light-exposed portion and a non-light-exposed portion were alternately provided. After the light exposure, the PAG layer was peeled off from the substrate and removed.

### [Evaluation of Patterning]

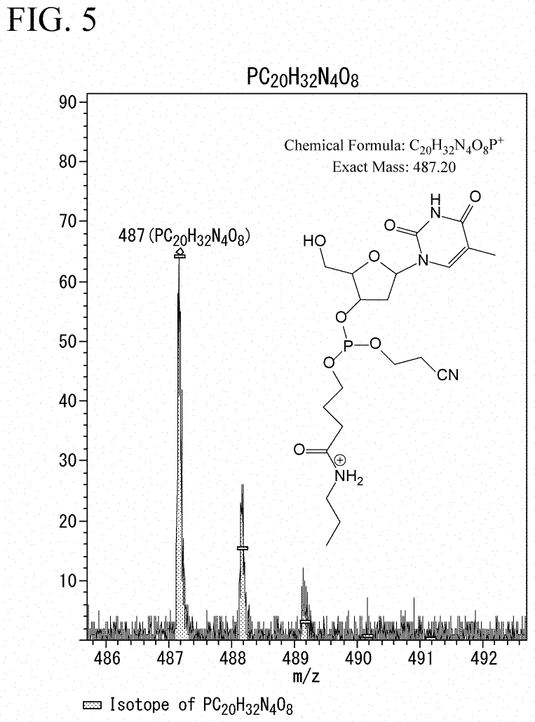

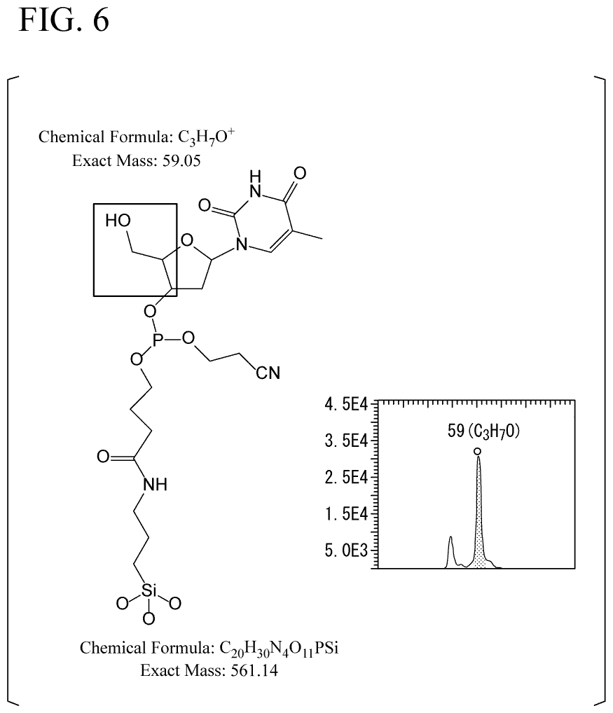

Mapping evaluation using mass distribution was performed by analyzing and interpreting the mass of the organic chemical structure on the substrate was using Time-of-flight secondary ion mass spectrometer (ToF-SIMS). At the time of analysis, the substrate was immersed and cleaned in acetone. FIGS. 5 and 6 show MS spectra of a portion deprotected using an acid. M/z 59 (FIG. 6) corresponding to fragment ion peaks and m/z=487 (FIG. 5) corresponding to molecule ion peaks were detected and it is possible to assign the deprotected structure.

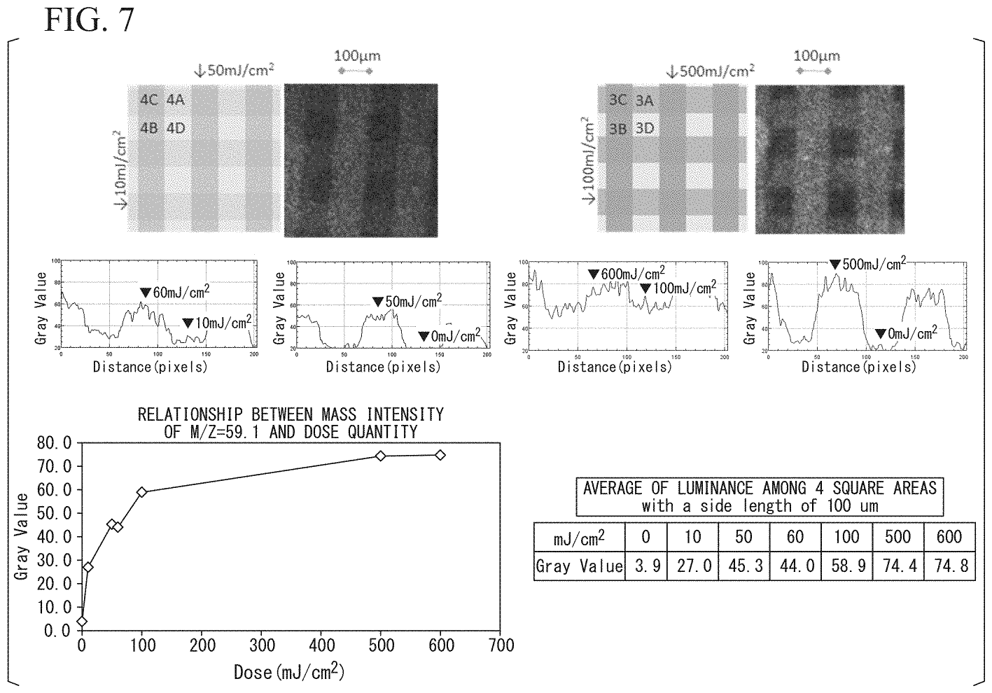

FIG. 7 shows the results of the mapping evaluation with a fragment ion m/z 59 in the substrate patterned in accordance with the present invention. It was seen that the number of deprotected structures increased in accordance with an amount of light exposure and that regioselective deprotection occurred.

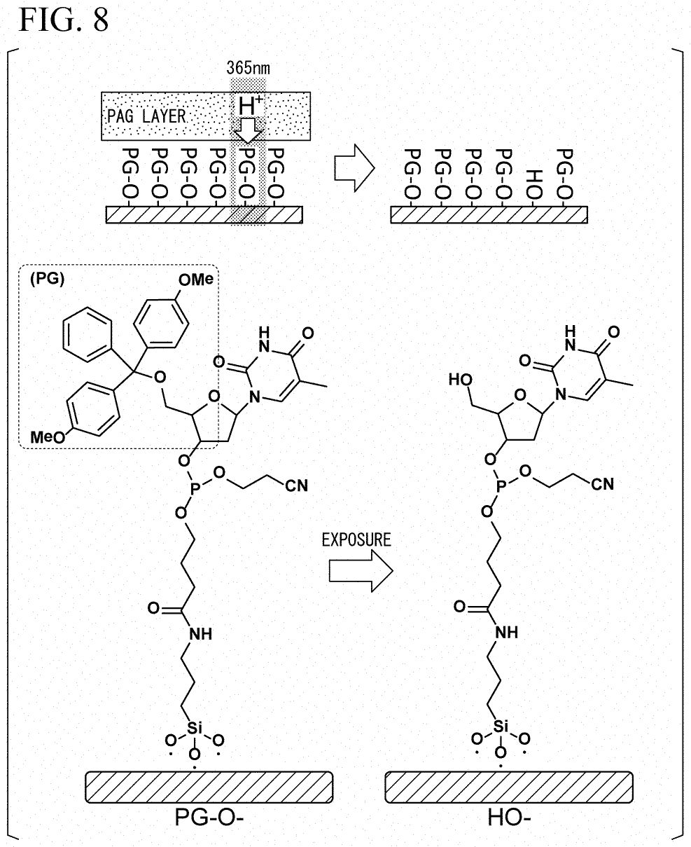

As shown in FIG. 8, since a hydroxyl group was able to be generated only in the light-exposed portion, it can be said that the present technology makes it possible to produce a DNA chip using light processing using an artificial DNA synthesis method such as a phosphoroamidite method.

### Example 2

### [Formation of Linker Layer on Substrate and Introduction of Acid-Decomposable Protective Group]

150 mg of a silane coupling agent (N-(3-triethoxysilylpropyl)-4-hydroxybutylamide manufactured by GELEST, INC.) was weighed in a beaker and 150 mL of ion exchange water heated to 90° C. was added into the beaker. After performing stirring at 90° C. for 5 minutes, 1.5 mL of acetic acid was added and the mixture was additionally heated and stirred for 30 minutes to form a silane solution.

Subsequently, a 3-inch silicon wafer with a 150 nm thermal oxide film serving as a substrate was treated and activated at 400 W×3 times using an atmospheric pressure oxygen plasma device (YAP510: manufactured by Yamato Scientific Co., Ltd.) and then was put into a reaction container and was heated with the silane solution at a set temperature of 90° C. for 20 minutes.

After the heating, the substrate was taken outside of the container, was immersed in isopropanol (IPA), and was subjected to 28 kHz ultrasonic cleaning for 5 minutes, and then was dried using a nitrogen flow. After that, the silane was fixed to the substrate by performing heating at 120° C. for 3 minutes to form a linker layer.

It should be noted that, if necessary, the linker layer was formed only on one side of the substrate by attaching a masking tape (N380 manufactured by Nitto Denko Corporation) to the one side thereof before the plasma treatment and peeling off the masking tape before the IPA cleaning.

Subsequently, the following work was performed in a glove box controlled to a nitrogen atmosphere of an oxygen concentration of 0.0% and a humidity of 3.3% or less.

20 mL of an acetonitrile solution of tetrazole (450 mM manufactured by Sigma-Aldrich) and 10 mL of dried acetonitrile (manufactured by Sigma-Aldrich) were added to 1 g of dimethoxytrityl (DMT)-dT phosphoroamidite (manufactured by Sigma-Aldrich). In this way, 30 mL of a 45 mM solution of DMT-dT phosphoroamidite was prepared.

As described above, the substrate having the linker layer formed thereon was immersed in the dried acetonitrile and was dried using a nitrogen flow. After the drying, the substrate was put into a reaction container and shaken with the DMT-dT phosphoroamidite solution for 2 minutes. The substrate was taken outside of the container and the dried acetonitrile was put into another container for transportation with the substrate and taken outside of the glove box.

The substrate was immersed in a container for cleaning containing 100 mL of acetonitrile and subjected to 28 kHz ultrasonic cleaning for 5 minutes. 100 mL of acetonitrile was prepared in another container and the same cleaning was performed twice or more, i.e., a total of 3 times. After the drying using a nitrogen flow, the substrate was stored in a glove box.

### [Preparation of Resin Composition]

PAG (CPI-210S manufactured by San-Apro Ltd.) was added to an alcohol solution (RusPack manufactured by Audeck Co., Ltd.) with a polyurethane concentration of 20% by mass to be 1% by mass (5% by mass with respect to polyurethane). The mixture was stirred using a rotary kneader and further irradiated with 28 kH ultrasonic waves for 5 minutes to completely dissolve the PAG. This was diluted 20 times with PGME and stirred using a rotary kneader.

### [Formation of PAG Layer]

A layer of the above-mentioned resin composition was spin-formed (1000 rpm and 30 seconds) on the substrate prepared as described above and the above-mentioned resin composition was heated and dried at 90° C. for 1 minute using a hot plate. The film thickness of the PAG layer was 60 nm.

### [Removal of Patterning and PAG Layer]

Pattern light exposure was performed using UV light of 365 nm. The pattern light exposure was performed at intervals of 5 μm so that an light-exposed portion and a non-light-exposed portion were alternately provided. After the light exposure, the PAG layer was peeled off from the substrate and removed.

### [Evaluation of Patterning]

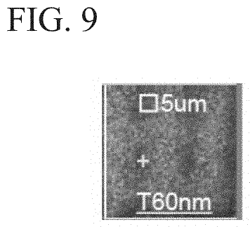

FIG. 9 shows the results of the mapping evaluation with a fragment ion m/z 59 in the substrate patterned in accordance with the present invention. It was seen that the number of deprotected structures increased in accordance with the amount of light exposure and that regioselective deprotection occurred.

As shown in FIG. 8, since a hydroxyl group was able to be generated only in the light-exposed portion, it can be said that the present technology makes it possible to produce a DNA chip using light processing using an artificial DNA synthesis method such as a phosphoroamidite method.

What is claimed is:

1. A method for producing a nucleic acid array, comprising:
(a) a step of forming a layer (a PAG layer) made of a resin composition containing a photo acid generator (PAG) for generating an acid as a result of being exposed to light on a solid phase which has a molecule immobilized thereon and having a functional group protected by an acid-decomposable protective group;
(b) a step of exposing a desired position of the PAG layer to light;
(c) a step of removing the PAG layer from which has been exposed to light; and
(d) a step of bringing the solid phase from which the PAG layer has been removed into contact with a nucleotide derivative having an acid-decomposable protective group.

2. The method for producing a nucleic acid array according to claim 1, wherein the step (c) is performed by peeling the PAG layer which has been exposed to light from the solid phase.

3. The method for producing a nucleic acid array according to claim 1, wherein the step (c) is performed by dissolving the PAG layer which has been exposed to light using a solvent.

4. The method for producing a nucleic acid array according to claim 1, wherein the step (c) includes cleaning the solid phase after removing the PAG layer which has been exposed to light.

5. The method for producing a nucleic acid array according to claim 1, wherein the resin contains a polyurethane resin.

6. The method for producing a nucleic acid array according to claim 1, wherein the PAG is selected from the group consisting of onium salts, diazomethanes, and sulfonic acid esters.

7. The method for producing a nucleic acid array according to claim 1, wherein an acid-decomposable protective group is selected from the group consisting of acetyl groups (Ac), benzoyl groups (Bz), trityl groups (Tr), monomethoxytrityl groups (MMT), dimethoxytrityl groups (DMT), trimethoxytrityl groups (TMT), β-methoxyethoxymethylethers (MEM), methoxy methyl ether groups (MOM), tetrahydropyranyl groups (THP), and t-butyldimethylsilyl groups (TBS).

8. The method for producing a nucleic acid array according to claim 1, wherein the steps (a) to (d) are repeatedly performed an arbitrary number of times.

9. A nucleic acid array production device comprising:
a PAG layer formation part which is configured to form a layer (a PAG layer) made of a resin composition containing a PAG for generating an acid as a result of being exposed to light on a solid phase which has a molecule immobilized thereon and having a functional group protected by an acid-decomposable protective group;
a light exposure part which is configured to expose a desired position of the PAG layer to light;
a PAG layer removal part which is configured to remove the PAG layer which has been exposed to light; and
a nucleotide derivative reaction part which is configured to bring the solid phase from which the PAG layer has been removed into contact with a nucleotide derivative having an acid-decomposable protective group.

10. The nucleic acid array production device according to claim 9, further comprising:
a solid phase moving part which is configured to move the solid phase between the PAG layer formation part, the light exposure part, and the PAG layer removal part; and
a solid phase moving controller which is configured to control the movement of the solid phase in the solid phase moving part.

11. The nucleic acid array production device according to claim 10, wherein the light exposure part includes a light source, the light source is disposed above the PAG layer formation part, and all or a part of the PAG layer formation part is also used as the light exposure part.

12. The nucleic acid array production device according to claim 9, wherein all or a part of the PAG layer formation part is also used as the PAG layer removal part.
